(19) United States
(12) Patent Application Publication
(10) Pub. No.: US 2023/0219120 A1
(43) Pub. Date: Jul. 13, 2023

(54) COVER PLATE BEARING DEVICE, COVER PLATE CLEANING DEVICE AND CLEANING METHOD FOR COVER PLATE

(71) Applicant: Bazhou Yungu Electronics Technology Co., Ltd., Langfang (CN)

(72) Inventor: Guangbin GAO, Langfang (CN)

(73) Assignee: Bazhou Yungu Electronics Technology Co., Ltd., Langfang (CN)

(21) Appl. No.: 18/184,776

(22) Filed: Mar. 16, 2023

Related U.S. Application Data
(63) Continuation of application No. PCT/CN2021/121074, filed on Sep. 27, 2021.

(30) Foreign Application Priority Data
Dec. 15, 2020 (CN) 202011473481.X

(51) Int. Cl. B08B 5/02; B08B 7/00; B08B 13/00; F16C 32/06

(52) U.S. Cl. CPC B08B 5/02; B08B 7/0035; B08B 13/00; F16C 32/0607

(57) ABSTRACT

A cover plate bearing device, a cover plate cleaning device, and a cover plate cleaning method. The cover plate bearing device includes a main body and a gas channel provided on the main body; the main body includes two side walls separated in a first direction, a bottom wall connected with the side walls, and a receiving cavity enclosed and formed by the side walls and the bottom wall; the shape of the receiving cavity matches that of the curved cover plate; at least one gas outlet of the gas channel are provided on the side wall; and the gas channel being adapted for blowing gas with a preset angle towards a side of the side wall facing away from the bottom wall, to prevent a moving fluid from eroding the functional coating of the curved cover plate.

### CROSS REFERENCES TO RELATED APPLICATIONS

The present application is a continuation of PCT Application No. PCT/CN2021/121074 filed on Sep. 27, 2021 and claims priority of Chinese Patent Application No. 202011473481.X, filed on Dec. 15, 2020 and titled “Cover Plate Bearing Device, Cover Plate Cleaning Device and Cleaning Method for Cover Plate”, content of which are incorporated here by reference in their entireties.

### TECHNICAL FIELD

The present application relates to the technical field of display device, and particularly relates to a cover plate bearing device, a cover plate cleaning device and a cleaning method for a cover plate.

### BACKGROUND

The “3D full bonding” production process of a flexible display product includes a process of bonding a glass cover plate with a panel, and this process requires plasma cleaning of a surface of the glass cover plate for bonding with the panel, that is, the bonding surface. In related technologies, there is a technical issue that a functional coating of a curved cover plate tends to be damaged during the cleaning process.

### SUMMARY

The embodiments of the present application provide a cover plate bearing device, a cover plate cleaning device and a cleaning method for a cover plate. The cover plate bearing device can prevent a surface on a side of a curved cover plate facing a receiving cavity from being damaged by a moving fluid, and thus can protect the curved cover plate from being damaged in performance and improving the yield of the curved cover plate.

On one aspect, the embodiments of the present application provide a cover plate bearing device adapted to bear a curved cover plate with a functional coating, the cover plate bearing device including:
a main body, including two side walls separated in a first direction, a bottom wall connected with the side walls, and a receiving cavity enclosed and formed by the side walls and the bottom wall, the receiving cavity matching the curved cover plate in shape; and
a gas channel, provided on the main body, at least one gas outlet of the gas channel being provided on the side wall, and the gas channel being adapted for blowing gas with a preset angle towards a side of the side wall facing away from the bottom wall, to prevent a moving fluid from eroding the functional coating of the curved cover plate.

The above cover plate bearing device provided by the present application can avoid damaging the functional coating on the side of the curved cover plate facing away from the bonding surface when cleaning the bonding surface of the curved cover plate, thereby helping to improve the yield of the curved cover plate.

Optionally, the at least one gas outlet is provided.

In the above embodiment, only one gas outlet is provided, so as to save production process and production time.

Optionally, the at least one gas outlet is located at a portion where the side wall and the bottom wall are connected, and/or at least one gas outlet are arranged along a side edge on a side of the side wall close to the receiving cavity.

In the above embodiment, the gas outlets are located at the portion where the side wall and the bottom wall are connected, or arranged along the side edge on a side of the side wall close to the receiving cavity, so as to facilitate blowing out the gas with a preset angle, and prevent plasma from entering a gap between the curved cover plate and the cover plate bearing device when cleaning the bonding surface of the curved cover plate with the plasma, thereby effectively preventing the plasma from contacting the functional coating of the curved cover plate and effectively protecting the functional coating.

Optionally, the cover plate bearing device further includes a gas supply device in communication with a gas inlet of the gas channel, the gas inlet is communicated with the gas supply device through a gas pipe, and the gas supply device is provided with clean and dry compressed air.

In the above embodiment, the gas supply device containing clean and dry compressed air is communicated with the gas inlet of the gas channel, so that clean and dry compressed air with a preset angle can be blown out from the gas outlet of the gas channel. On the one hand, the clean and dry compressed air blocks the plasma, and on the other hand, it will not affect the performance of the functional coating, and thus effectively prevent the functional coating from being damaged.

Optionally, the gas pipe is provided with a regulating valve for regulating a gas flow.

In the above embodiment, the gas pipe for communicating the gas inlet of the gas channel with the gas supply device is provided with the regulating valve, so as to facilitate the adjustment of the flow of gas ejected according to the actual plasma emission, thereby effectively preventing the plasma.

Optionally, the cover plate bearing device further includes two outer walls separated in a second direction, wherein the bottom wall and the side walls are connected with the outer walls;
the side walls, the bottom wall and the outer walls enclose and form the receiving cavity together,
wherein the first direction intersects the second direction.

In the above embodiment, the cover plate bearing device can not only bear the curved cover plate with two curved portions, but also can bear the curved cover plate with four curved portions. The application scope is further expanded, which can improve the utilization rate of the cover plate bearing device and save the process cost.

Optionally, the main body includes a plurality of vacuum adsorption channels, each vacuum adsorption channel includes a vacuum gas inlet and a vacuum gas outlet, the vacuum gas inlet is located on a surface of the bottom wall facing the receiving cavity, and the vacuum gas outlet is located on a surface of the main body facing away from the receiving cavity.

In the above embodiment, the main body is fixed with the curved cover plate by the manner of vacuum absorption, which can effectively prevent the damage of the curved cover plate and facilitate the fix and separation.

Optionally, the surface of the bottom wall facing the receiving cavity is provided with a plurality of vacuum suction cups corresponding to the vacuum gas inlets one by one. In the above embodiment, the bottom wall of the cover plate bearing device absorbs the curved cover plate by use of the vacuum suction cups, and the vacuum suction cups are made of flexible materials, thereby further protecting the curved cover plate and preventing occurrence of scratching.

According to one aspect of the present application, a cover plate cleaning device is further provided, which includes any cover plate bearing device provided by the first aspect of the present application, and a plasma emission device adapted to emit plasma to a surface to be cleaned of the curved cover plate.

According to one aspect of the present application, a cleaning method for a cover plate, applied with the cover plate cleaning device is provided, which includes steps of:
placing a curved cover plate with a functional coating in the receiving cavity of the cover plate bearing device, with the functional coating located on a side of the curved cover plate facing the cover plate bearing device;
aligning the cover plate bearing device with the plasma emission device, so that the plasma emission device is located on a side of the curved cover plate facing away from the cover plate bearing device and opposite to the curved cover plate;
blowing the gas with a preset angle towards the side of the side wall facing away from the bottom wall through the gas channel of the cover plate bearing device; and
emitting plasma by the plasma emission device to a surface of the side of the curved cover plate facing away from the cover plate bearing device to clean the curved cover plate.

The cover plate bearing device provided by the embodiments of the present application includes a main body and a gas channel, and the main body includes a side wall, a bottom wall and a receiving cavity. When in use, the curved cover plate is placed in the receiving cavity of the main body to make the bottom wall contact with the curved cover plate and thus bear the curved cover plate. The side wall surrounds a peripheral side of the curved cover plate to protect the curved cover plate. A gas outlet of the gas channel is formed on the side wall, and the gas channel is adapted for blowing a gas with a preset angle towards a side of the side wall facing away from the bottom wall. The gas is blown out with the preset angle through each outlet arranged on each side wall. The gas blown out of the gas channel is convection with the moving fluid, to prevent the moving fluid from contacting the surface of the curved cover plate facing the receiving cavity, and to prevent the functional coating on a surface of a side of the curved cover plate facing the receiving cavity from being damaged by the moving fluid, thereby protecting the curved cover plate from being damaged in the performance and improving the yield of curved cover plate.

### BRIEF DESCRIPTION OF THE DRAWINGS

In order to more clearly explain the technical solution of the embodiments of the present application, the following will briefly introduce the accompanying drawings needed to be used in the embodiments of the present application. Obviously, the accompanying drawings described below are merely some embodiments of the present application, and for the person skilled in the art, other accompanying drawings can be obtained from these accompanying drawings without expending creative labors.

FIG. 1 is a structural diagram of a cover plate bearing device provided by the embodiment of the present application;

FIG. 2 is a schematic cross-sectional view of FIG. 1 along line A-A;

FIG. 3 is an enlarged schematic diagram of portion B in FIG. 2;

FIG. 4 is a schematic diagram of the cover plate bearing device shown in FIG. 1 in use;

FIG. 5 is a schematic diagram showing a gas flow direction of a cover plate bearing device provided by the embodiment of the present application;

FIG. 6 is a cross-sectional view of another cover plate bearing device provided in the embodiment of the present application, of which positions of gas outlets are changed relative to the embodiments shown in FIG. 1 to FIG. 3;

FIG. 7 is an enlarged view of portion C in FIG. 6;

FIG. 8 is a structural diagram of a cover plate cleaning device provided by the embodiment of the present application; and

FIG. 9 is a flow chart of a cleaning method for a cover plate provided in the embodiment of the present application.

### DETAILED DESCRIPTION

Features and exemplary embodiments of various aspects of the present application will be described in detail below. In the following detailed description, many specific details are provided in order to provide a comprehensive understanding of the present application. However, it is obvious to the person skilled in the art that the present application can be implemented without some of these specific details. The following description of embodiments is only intended to provide a better understanding of the present application by showing examples.

The applicant has found through long-term research that: a glass cover plate includes a bonding surface used for bonding with a panel, and a side of the glass cover plate facing away from the bonding surface has a functional coating, which includes an anti-fingerprint coating; before bonding the glass cover plate with the panel, the bonding surface of the glass cover plate needs to be cleaned, and the common cleaning manner is plasma cleaning; before the plasma cleaning, the glass cover plate needs to be placed on a glass cover plate bearing platform, so that the anti-fingerprint coating is located on a side of the glass cover plate facing the glass cover plate bearing platform, and during the cleaning process, the plasma acts on the bonding surface of the glass cover plate, helping to remove oily substances on the bonding surface; however, when the glass cover plate bearing platform moves left and right, due to the influence of gas flow, some of the generated plasma will go cross the bonding surface, enter the gap between the glass cover plate bearing platform and the glass cover plate, and then come into contact with the anti-fingerprint coating of the glass cover plate, thereby damaging the anti-fingerprint coating.

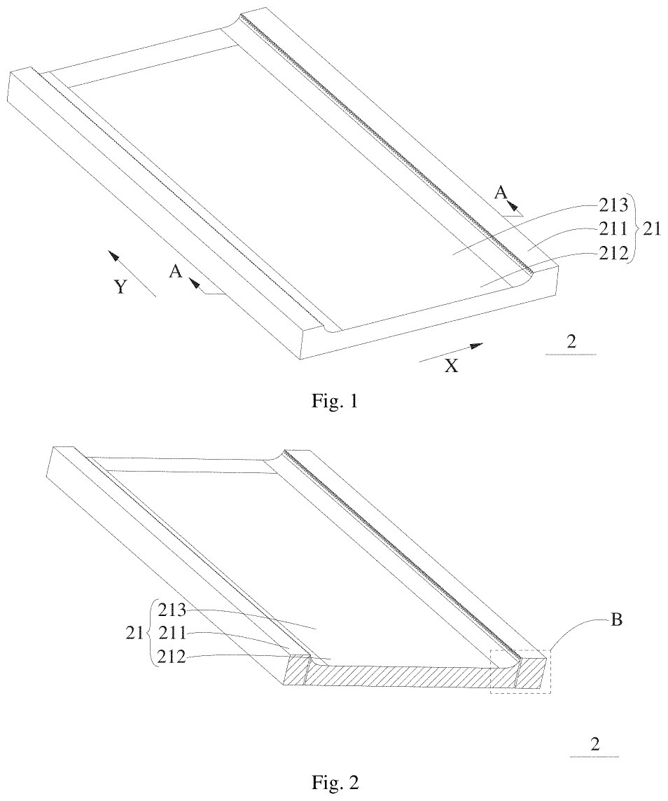

In order to better understand the present application, a cover plate bearing device 2, a cover plate cleaning device and a cleaning method for a cover plate in the embodiments of the present application are described in detail below in combination with FIGS. 1 to 7.

Referring to FIGS. 1, 2 and 3, the embodiment of the present application provides a cover plate bearing device 2, for bearing a curved cover plate 1 with a functional coating. The cover plate bearing device 2 includes a main body 21 and a gas channel 22 arranged on the main body 21, wherein the main body 21 includes two side walls 211 separated in a first direction, a bottom wall 212 connected with the side walls, and a receiving cavity 213 enclosed and formed by the side walls 211 and the bottom wall 212, and the receiving cavity 213 matches the curved cover plate in shape. At least one gas outlet 221 of the gas channel 22 is arranged on the side wall 211, and the gas channel 22 is adapted for blowing gas 5 with a preset angle towards a side of the side wall 211 facing away from the bottom wall 212 to prevent a moving fluid from eroding the functional coating of the curved cover plate 1.

The first direction refers to the X direction in FIG. 1, that is, the direction from one side wall 211 to the other side wall 211.

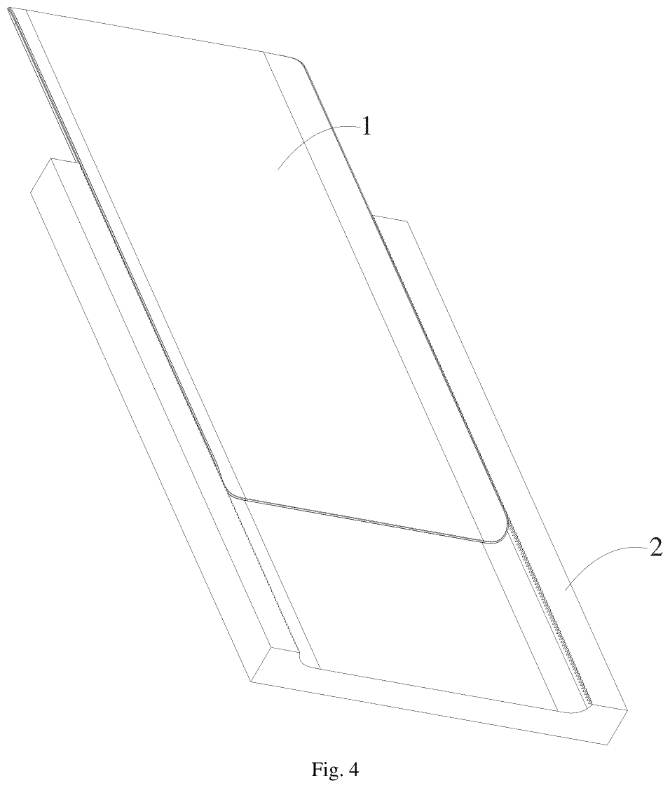

The embodiments of the present application provide the cover plate bearing device 2, the cover plate bearing device 2 includes the main body 21 and the gas channel 22, and the main body 21 includes the side walls 211, the bottom wall 212, and the receiving cavity 213. When in use, as shown in FIG. 4, the curved cover plate 1 is placed in the receiving cavity 213 of the main body 21, so that the bottom wall 212 contacts an area of the curved cover plate 1 provided with the functional coating and thus bears the curved cover plate 1, and the side walls 211 surround a peripheral side of the curved cover plate 1, to protect the curved cover plate 1; the side walls 211 are formed with the gas outlets 221 of the gas channels 22, and the gas channels 22 are adapted for blowing the gas 5 with the preset angle towards the sides of the side walls 211 away from the bottom wall 212, and the gas 5 is blown out at the preset angle through the respective gas outlets 221 arranged on the respective side walls 211; the gas 5 blown out from the gas channels 22 can form a convective flow with the moving fluid, and prevents the moving fluid from entering the gap between the curved cover plate 1 and the cover plate bearing device 2, thereby preventing the functional coating on the side of the curved cover plate 1 facing the receiving cavity 213 from being damaged by the moving fluid, and thus preventing the performance of the functional coating from being damaged and improving the yield of the curved cover plate 1.

In an available embodiment, the functional coating can be an anti-fingerprint coating, that is, the cover plate bearing device 2 provided in the present application can be used when cleaning the curved cover plate 1 provided with the anti-fingerprint coating by use of plasma 4, and the cover plate bearing device 2 can prevent the plasma 4 from damaging the anti-fingerprint coating. The present application takes this as an example, but the cover plate bearing device provided in the present application is not limited to be used when cleaning the curved cover plate 1 with the anti-fingerprint coating by use of the plasma 4.

Before bonding the curved cover plate 1 to a panel, a bonding surface for bonding the curved cover plate 1 with the panel needs to be cleaned, and generally is cleaned by use of the plasma 4. The side of the curved cover plate 1 facing away from the bonding surface is provided with the anti-fingerprint coating, and the plasma 4 for cleaning the bonding surface will damage the anti-fingerprint coating when it contacts with the anti-fingerprint coating, thus causing the failure of the anti-fingerprint function. By using the cover plate bearing device 2 provided in the present application, the curved cover plate 1 provided with the anti-fingerprint coating is placed in the receiving cavity 213, the anti-fingerprint coating is located on the side of the curved cover plate 1 facing the receiving cavity 213, and before cleaning the bonding surface with the plasma 4, the gas 5 with the preset angle can be blown out through the gas channels 22, so that when the plasma 4 is emitted towards the bonding surface, the gas 5 blown out from the gas channels 22 can form the convective flow with the plasma 4, and prevent the plasma 4 from contacting the anti-fingerprint coating, thereby avoiding the damage of the anti-fingerprint coating and improving the yield of the curved cover plate 1 cleaned by the plasma 4.

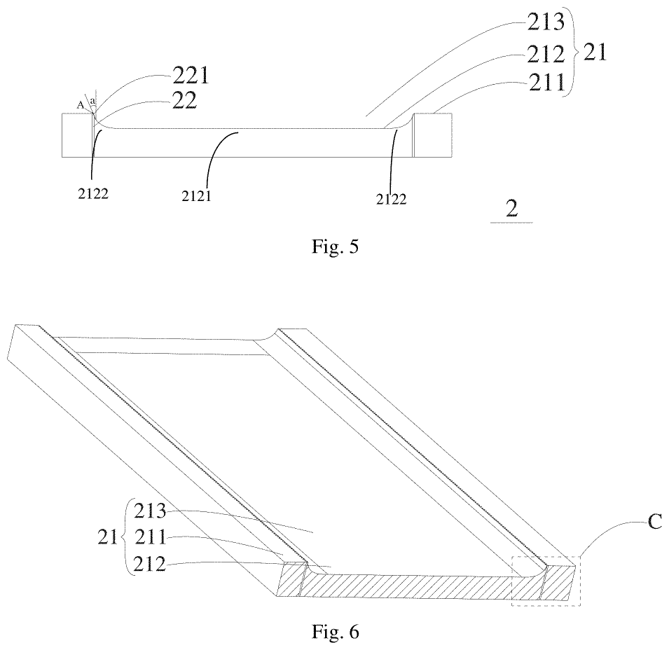

Specifically, the preset angle of the gas 5 is an angle by which the convective flow can prevent the oncoming fluid from contacting the functional coating. In the above embodiment, as shown in FIG. 5, the preset angle a ranges from a direction perpendicular to a surface of the bottom wall 212 to a direction tangent to a curved surface 2122 of the bottom wall 212 and the point A, where the point A is located on an edge on the side of side wall 211 facing away from the bottom wall 212 and facing the receiving cavity 213, and thus the contact between the plasma 4 and the anti-fingerprint coating can be prevented without affecting the contact between the plasma 4 and the bonding surface, that is, ensuring the cleaning effect.

Specifically, the bottom wall 212 includes a planar surface 2121 and at least one curved surface 2122 connected with each other, and the at least one curved surface 2122 is connected with the side wall 211. Specifically, the planar surface 2121 can contact a planar portion of the curved cover plate 1 provided with the functional coating, and the at least one curved surface 2122 can contact a curved portion of the curved cover plate 1 provided with the functional coating.

In an available embodiment, at least one gas outlet is provided. Specifically, there may be one gas outlet 221, so as to save the production process and production time.

In one available embodiment, at least one gas outlet 221 is located at a portion where the side wall 211 and the bottom wall 212 are connected. It can be understood that when only one gas outlet 221 is provided, the gas outlet 221 can be provided at the portion where the side wall 211 and the bottom wall 212 are connected; when a plurality of gas outlets 221 are provided, all the gas outlets 221 can be provided at the portion where the side wall 211 and the bottom wall 212 are connected.

In the above embodiments, the gas outlet 221 is located at the portion where the side wall 211 and the bottom wall 212 are connected, so as to facilitate the blowing out of the gas 5 with the preset angle and thus better block the oncoming plasma 4.

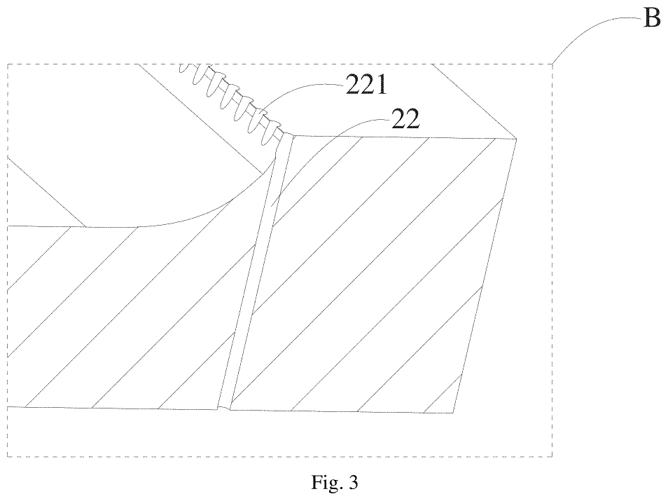

In one available embodiment, as shown in FIG. 3, a plurality of gas outlets 211 are provided and arranged along an extending direction of the side wall 211, each gas outlet 221 is located at the portion where the side wall 211 and the bottom wall 212 are connected, and specifically, adjacent two gas outlets 221 are arranged at intervals, and distances between respective adjacent two gas outlets 221 are the same.

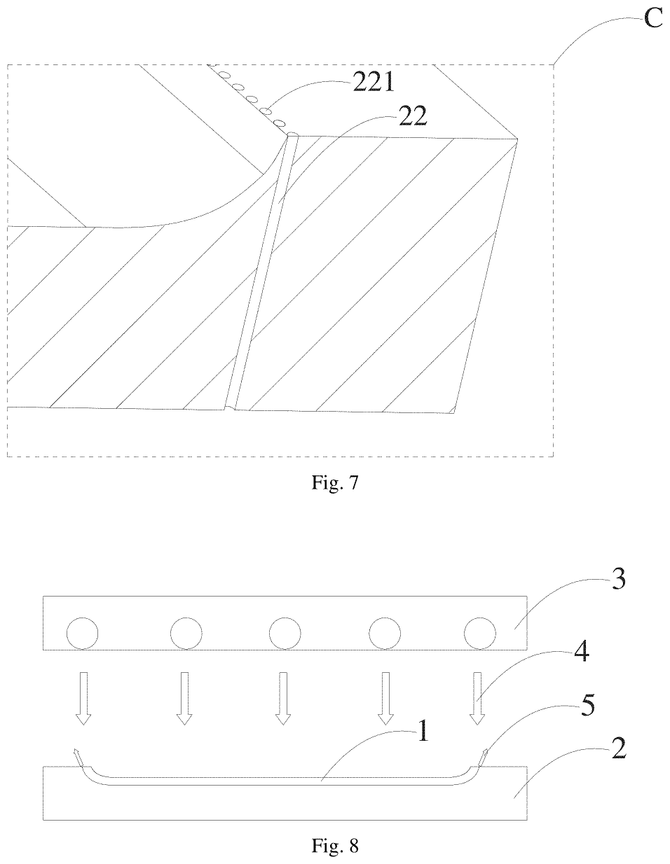

In another available embodiment, as shown in FIGS. 6 and 7, the side wall 211 includes a plurality of gas outlets 221; specifically, the plurality of gas outlets 221 are located on a top surface of the side of the side wall 211 facing away from the bottom wall, and the plurality of gas outlets 221 are arranged along a side edge on a side of the side wall 211 close to the receiving cavity 213. Specifically, adjacent two gas outlets 221 are arranged at intervals, and distances between respective adjacent two gas outlets 221 are the same.

In the above embodiments, the gas outlets 221 are located on the top surface of the side of the side wall 211 facing away from the bottom wall, which is convenient for fabrication, and is convenient for blowing out the gas 5 with the preset angle, thereby facilitating to block the plasma 4 emitted in a direction perpendicular to a surface of the bottom wall 212 facing the receiving cavity 213.

In one available embodiment, a plurality of gas outlets 221 are provided, and at least one gas outlet 221 is located at the portion where the side wall 211 and the bottom wall 212 are connected, while the remaining multiple gas outlets 221 are located at a top surface of the side of the side wall 211 facing away from the bottom wall 212. Further, the remaining multiple gas outlets 221 can be arranged along a side edge on the side of the side wall 211 close to the receiving cavity 213. With such arrangement, it is easier to block the plasma 4.

In one available embodiment, the cover plate bearing device 2 further includes a gas supply device (not shown in the figures) which is in communication with a gas inlet of the gas channel 22. The gas inlet is communicated with the gas supply device through a gas pipe, and the gas supply device is provided with clean and dry compressed air.

The clean and dry compressed air supply device in the above embodiment can be an air pump or the like, and the gas supply device is adapted to provide the clean and dry compressed air to the gas channel 22, so that when the gas 5 is blown out of the gas outlet 221, the gas 5 can not only block the oncoming plasma 4 without affecting the performance of the anti-fingerprint coating even if it contacts the anti-fingerprint coating, but also will not affect the cleaning effect of the bonding surface even if a small amount of the gas 5 contacts the bonding surface.

In one available embodiment, the gas pipe is provided with a regulating valve for regulating a flow of the gas 5, so that the flow of the gas 5 blown out through the gas channel 22 can be adjusted, thereby ensuring the convection effect relative to the moving fluid of the plasma 4, and the gas 5 can block all the plasma 4 forming a convective flow with the gas 5, prevent the plasma 4 from contacting the anti-fingerprint coating, and avoid damage to the anti-fingerprint coating.

In one available embodiment, as shown in FIG. 4, the side walls 211 are formed on two opposite sides of the bottom wall 212, so that the cover plate bearing device 2 can be applied to the curved cover plate 1 with two curved portions; alternatively, the cover plate bearing device 2 further includes two outer walls separated in a second direction (not shown in the figures), and the bottom wall 212 and side walls 211 are connected with the outer walls; the side walls 211, the bottom wall 212 and the outer walls together enclose and form the receiving cavity 213, wherein the second direction and the first direction intersect. Thus, the cover plate bearing device 2 can be applied to the curved cover plate 1 with four curved portions, and also to the curved cover plate 1 with two curved portions.

In a specific embodiment, the second direction is the Y direction as shown in FIG. 1, and in this embodiment, the first direction is perpendicular to the second direction. It can be seen that in other embodiments, besides perpendicularity, the positional relationship between the first direction and the second direction can be intersecting with other angles, which can be set according to the actual requirements.

In one available embodiment, the curved cover plate 1 is attached to the main body 21 by means of vacuum adsorption. The main body 21 has a plurality of vacuum adsorption channels (not shown in the figures), and each vacuum adsorption channel includes a vacuum gas inlet and a vacuum gas outlet, the vacuum gas inlet is located on a surface of the bottom wall 212 facing the receiving cavity 213, and the vacuum gas outlet is located on a surface of the main body 21 away from the receiving cavity 213.

In the above embodiment, the cover plate bearing device 2 fixes the curved cover plate 1 to be cleaned by means of vacuum adsorption, which has good fixing effect and is convenient for separation, and after separation, there is no residue on the curved cover plate 1.

In one available embodiment, the surface of the bottom wall 212 facing the receiving cavity 213 is provided with a plurality of vacuum suction cups (not shown in the figures) that correspond to the vacuum gas inlets one by one.

In the above embodiment, the cover plate bearing device 2 absorbs the curved cover plate 1 to be cleaned through the vacuum suction cups, and surfaces of the vacuum suction cups to be attached to the curved cover plate 1 are made of flexible materials, such as silica gel, so as to protect the curved cover plate 1 and avoid scratching the curved cover plate 1.

The present application further provides a cover plate cleaning device, as shown in FIG. 8, which includes any cover plate bearing device 2 provided by the above technical solutions and a plasma emission device, and the plasma emission device is adapted to emit plasma 4 to the surface to be cleaned of the curved cover plate 1.

The above cover plate cleaning device uses the plasma 4 to clean the surface to be cleaned, that is, the bonding surface of the curved cover plate 1. The cover plate cleaning device includes the cover plate bearing device 2, so that when cleaning the curved cover plate 1 with an anti-fingerprint coating, it can prevent the plasma 4 from damaging the anti-fingerprint coating, thereby improving the yield of the curved cover plate 1.

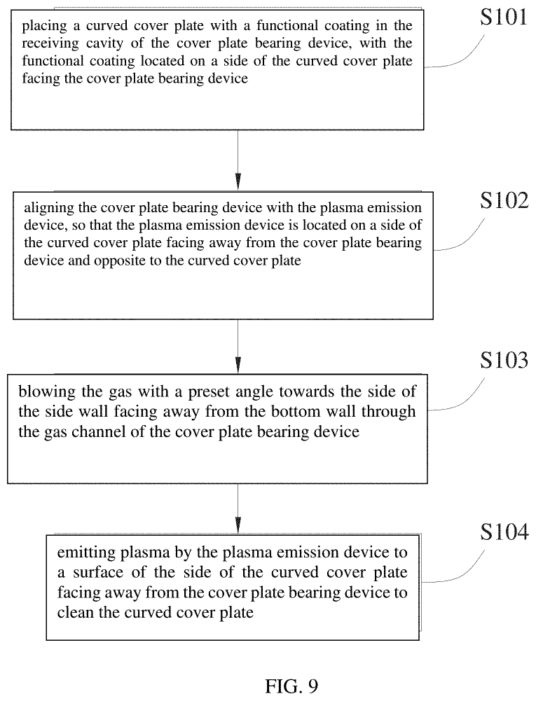

The present application further provides a cleaning method for a cover plate, and as shown in FIG. 9, the cleaning method for the cover plate uses the cover plate cleaning device provided in the above technical solutions, and includes steps of:
S101: placing the curved cover plate 1 with a functional coating in the receiving cavity 213 of the cover plate bearing device 2, with the functional coating located on a side of the curved cover plate 1 facing the cover plate bearing device 2;
S102: aligning the cover plate bearing device 2 with the plasma emission device 3, so that the plasma emission device 3 is located on a side of the curved cover plate 1 facing away from the cover plate bearing device 2 and opposite to the curved cover plate 1;
S103: blowing the gas 5 with a preset angle towards the side of the side wall 211 facing away from the bottom wall 212 through the gas channel 22 of the cover plate bearing device 2;
S104: emitting the plasma 4 by the plasma emission device 3 to a surface of the side of the curved cover plate 1 facing away from the cover plate bearing device 2 to clean the curved cover plate 1.

In the above cleaning method for the cover plate, the emission of the plasma 4 is performed after the gas 5 is blown out of the gas channel 22, and thus when the plasma 4 starts to emit, the plasma 4 near the edge of the curved cover plate 1 will form convective flow with respect to the gas 5 blown out of the gas outlet 221 on the side wall 211 of the cover plate bearing device 2, and thus is prevented from entering the receiving cavity 213 through the gap between the curved cover plate 1 and the cover plate bearing device 2, contacting and damaging the anti-fingerprint coating. The cleaning method for the cover plate provided in the present application can effectively prevent the plasma 4 from damaging the anti-fingerprint coating, and thus can further improve the yield of the curved cover plate 1.

The above are merely specific embodiments of the present application, and the person skilled in the art can clearly understand that, for the convenience and simplicity of description, the specific working process of the above described systems, modules and units can refer to the corresponding process in the above method embodiments, and will not be repeated here. It should be understood that the protection scope of the present application is not limited to this. Any person skilled in the art can easily think of various equivalent modifications or replacements within the technical scope disclosed in the present application, and these modifications or replacements should fall within the protection scope of the present application.

The exemplary embodiments mentioned in the present application describe some methods or systems based on a series of steps or devices. However, the present application is not limited to the order of the above steps, that is, the steps can be executed in the order mentioned in the embodiments, or in an order different from the order in the embodiments, or several steps can be executed simultaneously.

What is claimed is:

1. A cover plate bearing device adapted to bear a curved cover plate with a functional coating, the cover plate bearing device comprising:
a main body, comprising two side walls separated in a first direction, a bottom wall connected with the side walls, and a receiving cavity enclosed and formed by the side walls and the bottom wall, the receiving cavity matching the curved cover plate in shape; and
a gas channel, provided on the main body, at least one gas outlet of the gas channel being provided on the side wall, and the gas channel being adapted for blowing gas with a preset angle towards a side of the side wall facing away from the bottom wall, to prevent a moving fluid from eroding the functional coating of the curved cover plate.

2. The cover plate bearing device according to claim 1, wherein the at least one gas outlet is provided.

3. The cover plate bearing device according to claim 1, wherein the at least one gas outlet is located at a portion where the side wall and the bottom wall are connected.

4. The cover plate bearing device according to claim 1, wherein a plurality of gas outlets are provided, and the plurality of gas outlets are arranged in an extending direction of the side wall.

5. The cover plate bearing device according to claim 4, wherein the plurality of gas outlets are arranged at intervals, and distances between respective adjacent two gas outlets are the same.

6. The cover plate bearing device according to claim 4, wherein each gas outlet is located at a portion where the side wall and the bottom wall are connected.

7. The cover plate bearing device according to claim 4, wherein each gas outlet is located on a top surface of the side of the side wall facing away from the bottom wall.

8. The cover plate bearing device according to claim 7, wherein the plurality of gas outlets are arranged along a side edge on a side of the side wall close to the receiving cavity.

9. The cover plate bearing device according to claim 4, wherein part of the gas outlets are located at a portion where the side wall and the bottom wall are connected, and the other part of the gas outlets are located at a top surface of the side of the side wall facing away from the bottom wall.

10. The cover plate bearing device according to claim 9, wherein the other part of the gas outlets are arranged along a side edge on a side of the side wall close to the receiving cavity.

11. The cover plate bearing device according to claim 1, wherein the bottom wall comprises a planar surface and at least one curved surface connected to each other, and the curved surface is connected with the side wall; and
the preset angle ranges from a direction perpendicular to the bottom wall to a direction tangent to the curved surface and passing through an edge on the side of the side wall facing away from the bottom wall and facing the receiving cavity.

12. The cover plate bearing device according to claim 1, further comprising a gas supply device in communication with a gas inlet of the gas channel, wherein the gas supply device is provided with clean and dry compressed air.

13. The cover plate bearing device according to claim 12, wherein the gas inlet is communicated with the gas supply device through a gas pipe.

14. The cover plate bearing device according to claim 13, wherein the gas pipe is provided with a regulating valve for regulating a gas flow.

15. The cover plate bearing device according to claim 1, further comprising two outer walls separated in a second direction, wherein the bottom wall and the side walls are connected with the outer walls;
the side walls, the bottom wall and the outer walls enclose and form the receiving cavity together,
wherein the first direction intersects the second direction.

16. The cover plate bearing device according to claim 1, wherein the main body comprises a plurality of vacuum adsorption channels, each vacuum adsorption channel comprises a vacuum gas inlet and a vacuum gas outlet, the vacuum gas inlet is located on a surface of the bottom wall facing the receiving cavity, and the vacuum gas outlet is located on a surface of the main body facing away from the receiving cavity.

17. The cover plate bearing device according to claim 16, wherein the surface of the bottom wall facing the receiving cavity is provided with a plurality of vacuum suction cups corresponding to the vacuum gas inlets one by one.

18. The cover plate bearing device according to claim 17, wherein surfaces of the vacuum suction cups to be attached to the curved cover plate are made of flexible material.

19. A cover plate cleaning device comprising:
the cover plate bearing device according to claim 1, and a plasma emission device adapted to emit plasma to a surface to be cleaned of the curved cover plate.

20. A cleaning method for a cover plate, applied with the cover plate cleaning device according to claim 19, comprising:
placing a curved cover plate with a functional coating in the receiving cavity of the cover plate bearing device, with the functional coating located on a side of the curved cover plate facing the cover plate bearing device;
aligning the cover plate bearing device with the plasma emission device, so that the plasma emission device is located on a side of the curved cover plate facing away from the cover plate bearing device and opposite to the curved cover plate;
blowing the gas with a preset angle towards the side of the side wall facing away from the bottom wall through the gas channel of the cover plate bearing device; and
emitting plasma by the plasma emission device to a surface of the side of the curved cover plate facing away from the cover plate bearing device, to clean the curved cover plate.
